(19) United States
(12) Patent Application Publication
(10) Pub. No.: US 2012/0031451 A1
(43) Pub. Date: Feb. 9, 2012

(54) HIGH TEMPERATURE THERMOELECTRIC GENERATOR

(75) Inventors: Robert Cox, Charlotte, NC (US); Ivan Howitt, Charlotte, NC (US); Karunakar Reddy Gujja, Charlotte, NC (US)

(73) Assignee: THE UNIVERSITY OF NORTH CAROLINA AT CHARLOTTE, Charlotte, NC (US)

(21) Appl. No.: 12/849,894

(22) Filed: Aug. 4, 2010

(51) Int. Cl. H01L 35/30

(52) U.S. Cl. 136/205

(57) ABSTRACT

The present invention relates to a high temperature thermoelectric generator. The generator includes at least one thermocouple thermally connected to a high temperature surface, a power management circuit adapted to receive electric power from the at least one thermocouple and provide a regulated output voltage, and a storage device adapted to receive the regulated output voltage from the power management circuit such that the output voltage charges the storage device.

### BACKGROUND OF THE INVENTION

The present invention relates generally to energy harvesting devices, and more particularly, to a high temperature thermoelectric generator.

A major roadblock preventing the widespread deployment of wireless sensor devices is the need for reliable, continuously available power sources. One option is to provide these devices with a means to harvest energy from ambient sources such as sunlight, vibrations, and waste heat.

However, commercially available thermal energy-harvesting devices are temperature limited. These units use Peltier elements featuring small semiconductor sections attached to a conducting sheet. Typical modules of this type are described in U.S. Pat. No. 4,855,810 issued to Gelb et al. According to the prior art, the solder attaching these semiconductor elements to conducting sheets can fail at temperatures approaching 250 degrees Celsius (° C.) (U.S. Pat. No. 5,817,188). Further, in some instances, the tin in the solder can diffuse into the semiconductor sections where it can act as a dopant or reactant, thus degrading performance over time.

Accordingly, there is a need for a device that overcomes these temperature limitations, which can be a hindrance in many industrial settings such as thermal power plants.

### BRIEF SUMMARY OF THE INVENTION

These and other shortcomings of the prior art are addressed by the present invention, which provides a means for harvesting energy from surfaces with temperatures well in excess of 300° C.

According to one aspect of the present invention, a high temperature thermoelectric generator includes at least one thermocouple thermally connected to a high temperature surface; a power management circuit adapted to receive electric power from the at least one thermocouple and provide a regulated output voltage; and a storage device adapted to receive the regulated output voltage from the power management circuit such that the output voltage charges the storage device.

According to another aspect of the present invention, a high temperature thermoelectric generator includes a thermopile having a plurality of high temperature thermocouples thermally connected to a high temperature surface, the thermocouples each producing an output voltage in response to a temperature difference between a hot junction and a cold junction of the thermocouples. The generator also includes a power management circuit having a DC/DC converter adapted to receive the output voltage from the plurality of high temperature thermocouples and provide a regulated DC output voltage; a battery adapted to receive the DC output voltage from the power management circuit, wherein the DC output voltage charges the battery and the battery stores electric power; and an application device electrically connected to the power management circuit and the battery and adapted to receive electric power from one or both of the power management circuit and battery.

According to another aspect of the present invention, A high temperature thermoelectric generator includes a thermopile thermally connected to a high temperature surface and adapted to produce an output voltage in response to a temperature difference; a power management circuit adapted to receive the output voltage from the thermopile and provide a regulated output voltage; and a storage device adapted to receive the regulated output voltage from the power management circuit, wherein the regulated output voltage charges the storage device and the storage device stores electric power.

### BRIEF DESCRIPTION OF THE DRAWINGS

The subject matter that is regarded as the invention may be best understood by reference to the following description taken in conjunction with the accompanying drawing figures in which:

FIG. 1 is a block diagram of a high temperature thermoelectric generator according to an embodiment of the invention;

FIG. 2 is a connection diagram of a thermopile of the generator of FIG. 1;

FIG. 3 shows a high temperature thermoelectric generator according to an embodiment of the invention;

FIG. 4 shows battery voltage during testing using the generator of FIG. 3; and

FIG. 5 shows battery current during testing using the generator of FIG. 3.

### DETAILED DESCRIPTION OF THE INVENTION

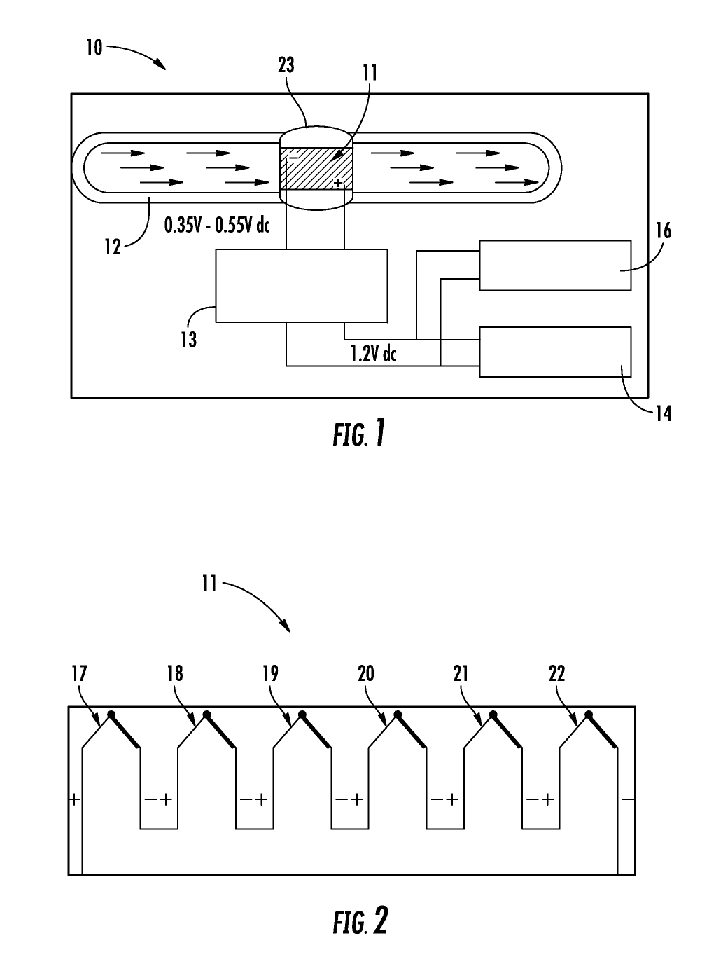

Referring to the drawings, an exemplary high temperature thermoelectric generator is illustrated in FIG. 1 and shown generally at reference numeral 10. In general, the generator 10 uses a combination of thermocouples and associated power management circuitry to charge an energy storage device such as a battery or a capacitor. The storage element may also act as a power source for a sensor device and associated circuitry.

A shown, an appropriate collection of thermocouples are combined to form a thermopile 11. The thermopile 11 is attached to a high temperature surface 12, such as a steam pipe or engine. Electric power generated by the thermopile 11 is provided to a power management circuit 13 that provides a regulated output voltage. The power management circuit 13 can either step up or step down the voltage as needed. This output is used to charge an energy-storage element 14, such as a battery or capacitor or any other viable storage device, and to power an application device 16, such as microprocessors, sensors and associated sensing circuitry, and/or radios and associated radio circuitry.

Referring to FIG. 2, the thermopile 11 includes six individual thermocouple elements 17-22 connected electrically in series. Individual thermocouples consist of two dissimilar metals and produce an output voltage that is proportional to the temperature difference between a hot junction where the two metals are joined and a cold junction where the output terminals are exposed. The dark circles are the hot (i.e. high temperature) junctions.

In the configuration shown, the output voltage measured across the terminals is the sum of the voltages produced by each of the individual thermocouple elements. The number and connection of thermocouples depends on the specifics of the application (i.e. temperature, voltage and current requirements). The hot junction of each thermocouple is placed on a common conducting sheet, and each is adhered to the surface via a means that provides electrical isolation and high thermal conductivity. Several conducting sheets, each with one or more thermopiles, can be used. The individual thermopiles may be connected electrically in series or in parallel as needed. Appropriate thermal insulation 23 (shown in FIG. 1) may be placed on top of the conducting sheet as needed.

Thermocouple elements have the advantage that they can operate up to very high temperatures. Appropriate temperature ranges for common thermocouple elements (Kinzie 1973) are shown in Table 1. Note that the maximum temperature for Type B thermocouples is up to 1800° C., far exceeding that achievable by semiconductor-based Pettier elements. This high temperature range is desirable in many industrial settings, such as power plants where surfaces can exceed 500° C.

TABLE 1

| Type | Composition | Range | Sensitivity |
|---|---|---|---|
| Type K | Chromel (Ni—Cr | −250° C. to | 41 μV/° C. |
| | Alloy)/Alumel (Ni—Al | 1200° C. | |
| | Alloy) | | |
| Type E | Chromel/Constantan | −250° C. to | 68 μV/° C. |
| | (Cu—Ni Alloy) | 900° C. | |
| Type J | Iron/Constantan | −40° C. to | 52 μV/° C. |
| | | 900° C. | |
| Type N | Nicrosil (Ni—Cr—Si | −270° C. to | 39 μV/° C. |
| | Alloy)/Nisil (Ni—Si | 1300° C. | |
| | Alloy) | | |
| Type T | Copper/Constantan | −200° C. to | 43 μV/° C. |
| | | 350° C. | |
| Type R | Platinum/Platinum | 0° C. to | 10 μV/° C. |
| | with 13% Rhodium | 1600° C. | |
| Type S | Platinum/Platinum | 0° C. to | 10 μV/° C. |
| | with 10% Rhodium | 1600° C. | |
| Type B | Platinum- | 50° C. to | 10 μV/° C. |
| | Rhodium/Pt—Rh | 1800° C. | |

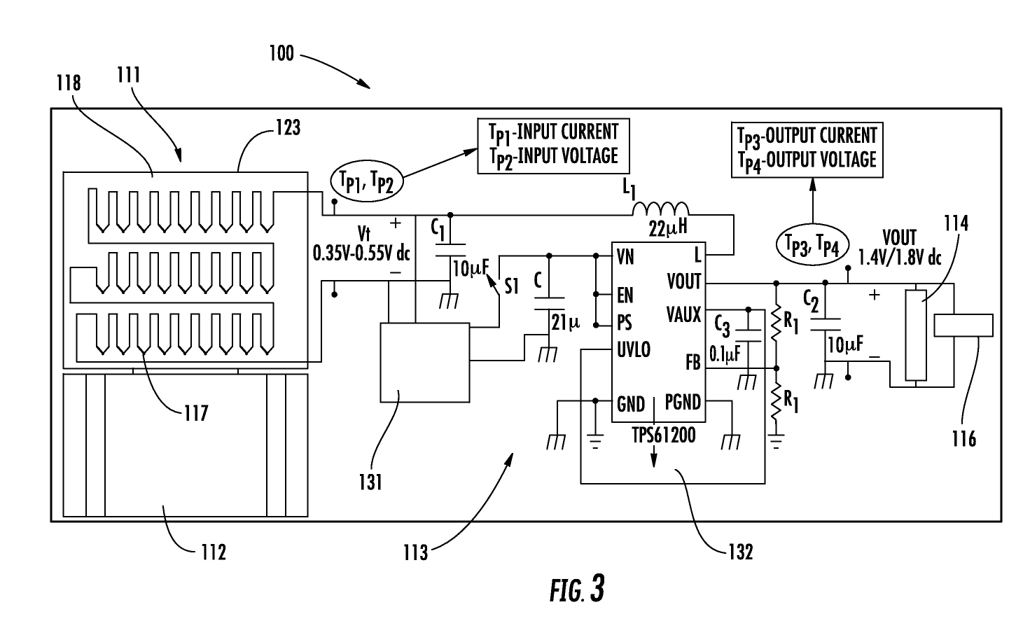

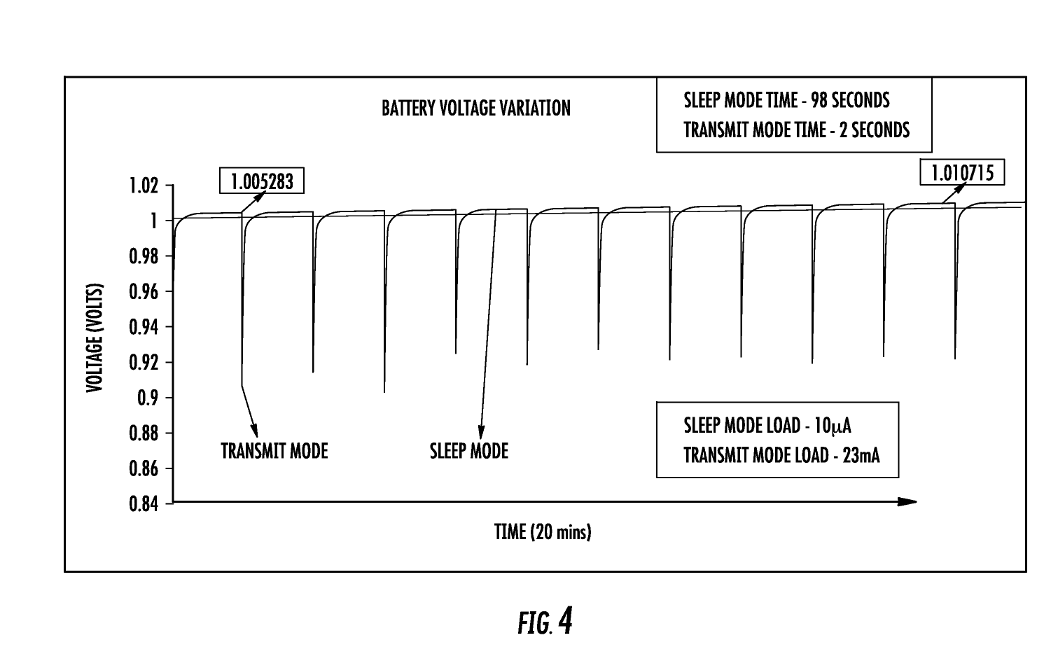

Referring to FIG. 3, an example generator 100 was used to conduct tests and determine the effectiveness of a generator like that described above with respect to generator 10. Generator 100 includes a thermopile transducer assembly 111, a power management circuit 113, a storage device 114, and an application device 116. The thermopile 111 consists of thirty thermocouple elements 117. Electrically, these elements 117 are connected in series; thermally, they are connected in parallel. Each thermocouple 117 is placed on an aluminum bar 118 and each is adhered to a surface using a high temperature ceramic adhesive. The aluminum bar 118 is placed on a hot plate 112 with a temperature of 300° C. Thermal insulation 123 is wrapped around the assembly.

The output from the thermopile transducer 111 is provided to the power management circuit 113, which consists of a charge-pump circuit 131 to step or step down the voltage and a DC-to-DC converter 132 to regulate the voltage. The converter 132 supplies 1.4V DC to the storage device 114 and the application device 116. In this case, the storage device 114 is a 1.2V, 2000 mAh NiMH rechargeable battery, and the application device 116 is a programmable load designed to emulate a wireless sensor device. The programmable load is configured to draw 23 mA for 2 seconds at 100 second intervals. In between these bursts, the load draws 10 μA. These values are purposely pessimistic assumptions based on field measurements of existing wireless devices.

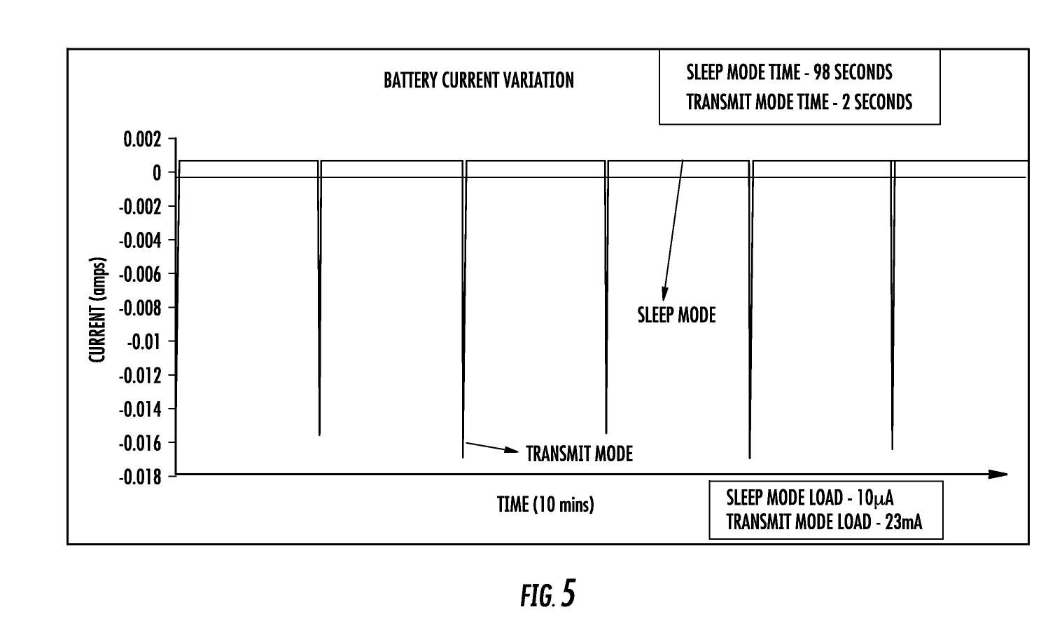

The results of the tests are shown in FIGS. 4 and 5. FIG. 4 shows the battery voltage over a 20 minute period, and FIG. 5 shows the battery current during a portion of that period. Note that the battery is charged during the 98 second sleep intervals and discharged slightly during the 2 second transmit intervals. An overall net charge is observed. It should be appreciated that the generator 100 represents an example generator and is not intended to limit the scope of the invention.

The foregoing has described a high temperature thermoelectric generator. While specific embodiments of the present invention have been described, it will be apparent to those skilled in the art that various modifications thereto can be made without departing from the spirit and scope of the invention. Accordingly, the foregoing description of the preferred embodiment of the invention and the best mode for practicing the invention are provided for the purpose of illustration only and not for the purpose of limitation.

We claim:

1. A high temperature thermoelectric generator, comprising:
(a) at least one thermocouple thermally connected to a high temperature surface;
(b) a power management circuit adapted to receive electric power from the at least one thermocouple and provide a regulated output voltage; and
(c) a storage device adapted to receive the regulated output voltage from the power management circuit such that the output voltage charges the storage device.

2. The high temperature thermoelectric generator according to claim 1, further including an application device adapted to receive the regulated output voltage from the power management circuit.

3. The high temperature thermoelectric generator according to claim 2, wherein the application device is selected from the group consisting of microprocessors, sensors, sensing circuitry, radios, and radio circuitry.

4. The high temperature thermoelectric generator according to claim 1, further including an application device adapted to receive electric power from the storage device.

5. The high temperature thermoelectric generator according to claim 1, wherein the storage device is selected from the group consisting of a battery and a capacitor.

6. The high temperature thermoelectric generator according to claim 1, wherein a hot junction of the at least one thermocouple is adhered to a conducting sheet to provide electrical isolation and high thermal conductivity.

7. The high temperature thermoelectric generator according to claim 6, wherein the conducting sheet is thermally connected to the high temperature surface.

8. A high temperature thermoelectric generator, comprising:
(a) a thermopile having a plurality of high temperature thermocouples thermally connected to a high temperature surface, the thermocouples each producing an output voltage in response to a temperature difference between a hot junction and a cold junction of the thermocouples;
(b) a power management circuit having a DC/DC converter adapted to receive the output voltage from the plurality of high temperature thermocouples and provide a regulated DC output voltage;
(c) a battery adapted to receive the DC output voltage from the power management circuit, wherein the DC output voltage charges the battery and the battery stores electric power; and
(d) an application device electrically connected to the power management circuit and the battery and adapted to receive electric power from one or both of the power management circuit and battery.

9. The high temperature thermoelectric generator according to claim 8, wherein the thermopile further includes an aluminum bar for mounting the thermocouples thereto.

10. The high temperature thermoelectric generator according to claim 8, wherein the plurality of thermocouples are electrically connected in series.

11. The high temperature thermoelectric generator according to claim 8, wherein the hot junction of each of the plurality of thermocouples are connected to a surface of a conducting sheet.

12. The high temperature thermoelectric generator according to claim 11, wherein the hot junction of each of the plurality of thermocouples is adhered to the surface of the conducting sheet with a high temperature ceramic adhesive.

13. The high temperature thermoelectric generator according to claim 8, further including thermal insulation wrapped around the thermopile.

14. The high temperature thermoelectric generator according to claim 8, wherein the power management circuit further includes a charge pump circuit.

15. The high temperature thermoelectric generator according to claim 8, wherein the application device is selected from the group consisting of microprocessors, sensors, sensing circuitry, radios, and radio circuitry.

16. A high temperature thermoelectric generator, comprising:
(a) a thermopile thermally connected to a high temperature surface and adapted to produce an output voltage in response to a temperature difference;
(b) a power management circuit adapted to receive the output voltage from the thermopile and provide a regulated output voltage; and
(c) a storage device adapted to receive the regulated output voltage from the power management circuit, wherein the regulated output voltage charges the storage device and the storage device stores electric power.

17. The high temperature thermoelectric generator according to claim 16, further including an application device electrically connected to the power management circuit and the storage device and adapted to receive electric power from one or both of the power management circuit and storage device.

18. The high temperature thermoelectric generator according to claim 16, wherein the thermopile includes:
(a) a conducting sheet adapted to be thermally connected to the high temperature surface; and
(b) at least one thermocouple having a hot junction adhered to the conducting sheet.

19. The high temperature thermoelectric generator according to claim 18, wherein the thermopile includes a plurality of thermocouples connected in series.

20. The high temperature thermoelectric generator according to claim 18, wherein the thermopile further includes a thermal insulation wrapped around the conductive sheet and at least one thermocouple.
